(19) United States
(12) Patent Application Publication
(10) Pub. No.: US 2024/0223146 A1
(43) Pub. Date: Jul. 4, 2024

(54) AMPLIFIER WITH ADJUSTABLE INPUT AND FEEDBACK RESISTANCE

(71) Applicant: Analog Devices International Unlimited Company, Limerick (IE)

(72) Inventors: Suhas V. Dixith, Mysore (IN); Mayank Devam, Bengaluru (IN); Daniel Peter Canniff, Brookline, MA (US); Rajeev S. Morajkar, Boxborough, MA (US); Preston S. Birdsong, Medfield, MA (US)

(21) Appl. No.: 18/398,638

(22) Filed: Dec. 28, 2023

Related U.S. Application Data
(60) Provisional application No. 63/477,839, filed on Dec. 30, 2022.

(51) Int. Cl. H03G 3/30; H03F 3/45

(52) U.S. Cl. CPC H03G 3/30; H03F 3/45475; H03G 2201/103

(57) ABSTRACT

A programmable gain amplifier (PGA) circuit for adjusting a signal gain between a signal input and a signal output can include a differential-input amplifier which can include a first input node, a second input node, and a first output node, where the differential-input amplifier can be configured to amplify a difference in signal level between the first input node and the second input node for being provided on the first output node. The PGA circuit can also include a first configurable input impedance circuit, which can be arranged between a first signal input node and the first input node, which can be configured to provide a first specified input impedance value. The PGA circuit can also include a first configurable feedback impedance circuit, which can be arranged between a first signal output node and the first input node, which can be configured to provide a first specified feedback impedance value.

### CLAIM OF PRIORITY

This patent application claims the benefit of priority of Dixith et al., U.S. Provisional Patent Application Ser. 63/477,839, entitled “PROGRAMMABLE GAIN AMPLIFIER WITH A CONSTANT INPUT IMPEDANCE,” filed on Dec. 30, 2022 (Attorney Docket No. 3867.A74PRV), which is hereby incorporated by reference herein in its entirety.

### TECHNICAL FIELD

The present disclosure relates to amplifiers, and more particularly, but not by way of limitation, to a programmable gain amplifier with an adjustable input resistance string and an adjustable feedback resistance string.

### BACKGROUND

Amplifier circuits are used in electronic systems for a variety of applications. For example, an analog amplifier circuit can be used in combination with other circuit types, such as co-integrated on a monolithic integrated circuit or in an integrated circuit package. An amplifier circuit can be configured to provide a fixed or adjustable gain. For example, gain programmability can include either amplification or attenuation, or both.

In analog signal processing applications, such as in automotive, wireless communication, or networking applications, it can be desirable to modify an amplitude range of an incoming analog signal, such as before downstream analog processing or digitization. A programmable-gain amplifier (PGA) circuit can provide gain adjustability, such as controlled by digital or analog signals provided by other elements in a signal processing system.

### SUMMARY

In an example, a programmable gain amplifier (PGA) circuit for adjusting a signal gain between a signal input and a signal output can include a differential-input amplifier which can include a first input node, a second input node, and a first output node, where the differential-input amplifier can be configured to amplify a difference in signal level between the first input node and the second input node for being provided on the first output node. The PGA circuit can also include a first configurable input impedance circuit, arranged between a first signal input node and the first input node, where the first configurable input impedance circuit can be configured to provide a first specified input impedance value, where the first configurable input impedance circuit can include a first series arrangement of a first plurality of resistors, where a first end of the first series arrangement can be coupled to the first signal input node, where respective connection points between respective ones of the first plurality of resistors can define respective input impedance tap points, and a first plurality of switches, where a first end of respective ones of the first plurality of switches can be coupled to the first input node and a second end of the respective ones of the first plurality of switches can be coupled to corresponding ones of the input impedance tap points. The PGA circuit can also include a first configurable feedback impedance circuit, which can be arranged between a first signal output node and the first input node, where the first configurable feedback impedance circuit is configured to provide a first specified feedback impedance value, where the first configurable feedback impedance circuit can include a second series arrangement of a second plurality of resistors, where a first end of the second series arrangement can be coupled to the first signal output node, where respective connection points between respective ones of the second plurality of resistors can define respective feedback impedance tap points, and a second plurality of switches, where a first end of respective ones of the second plurality of switches can be coupled to the first input node and a second end of the respective ones of the second plurality of switches can be coupled to corresponding ones of the feedback impedance tap points.

### BRIEF DESCRIPTION OF THE DRAWINGS

In the drawings, which may not be drawn to scale, like numerals may describe substantially similar components throughout one or more of the views. Like numerals having different letter suffixes may represent different instances of substantially similar components. The drawings illustrate generally, by way of example but not by way of limitation.

FIG. 1 shows an example of a portion of a PGA circuit.

FIG. 2 shows an example of a portion of a PGA circuit.

FIG. 3 shows an example of a portion of the PGA circuit of FIG. 2 and an example of an application circuit in which the PGA circuit can be used.

FIG. 4 shows a plot of simulated operating characteristics of a PGA circuit as shown in FIG. 3.

FIG. 5 shows a plot of simulated operating characteristics of a PGA circuit as shown in FIG. 3.

FIG. 6 shows a plot of simulated operating characteristics of a PGA circuit as shown in FIG. 3.

FIG. 7 shows an example of portions of a method for operating a PGA circuit.

FIG. 8 is a block diagram illustrating an example of a machine upon which one or more examples may be implemented.

### DETAILED DESCRIPTION

The present inventors have recognized, among other things, that it can be desirable for a programmable gain amplifier (PGA) circuit to include adjustable gain steps that are at or below a specified gain step threshold. This can help to provide an output signal where artifacts are suppressed or below a threshold of perception by a user. For example, in audio applications, users of the system may perceive an audible artifact such as a pop or click corresponding to a gain value change. Providing gain steps at or below the specified gain step threshold can reduce or eliminate such artifacts. The present inventors have recognized, among other things, that implementation of such a specified gain step can be accomplished by using a circuit topology having a coarse gain control and a fine gain control. For example, the fine gain control can be stepped through fine gain increments, and once all available fine gain increments are used, a coarse gain control can be stepped through a coarse gain increment and the fine gain control can be reset, such as to produce a specified a step size corresponding to the fine gain increment. Such an approach can also be used for gain decrements.

The present inventors have recognized, among other things, that it can also be desirable to provide a stable input impedance to the PGA circuit across the adjustable gain range. For example, the approach described herein can be used to help limit a change in the input impedance of a PGA circuit across gain values, such as by limiting such an impedance change to a specified range or value. This can help provide one or more of more stable corner frequency or pole location for upstream filters (e.g., a filter formed by a resistor in series with a capacitor, such as can be affected by the input impedance of the PGA circuit), or a more linear effective gain, as compared to a PGA circuit having a larger variation in input impedance.

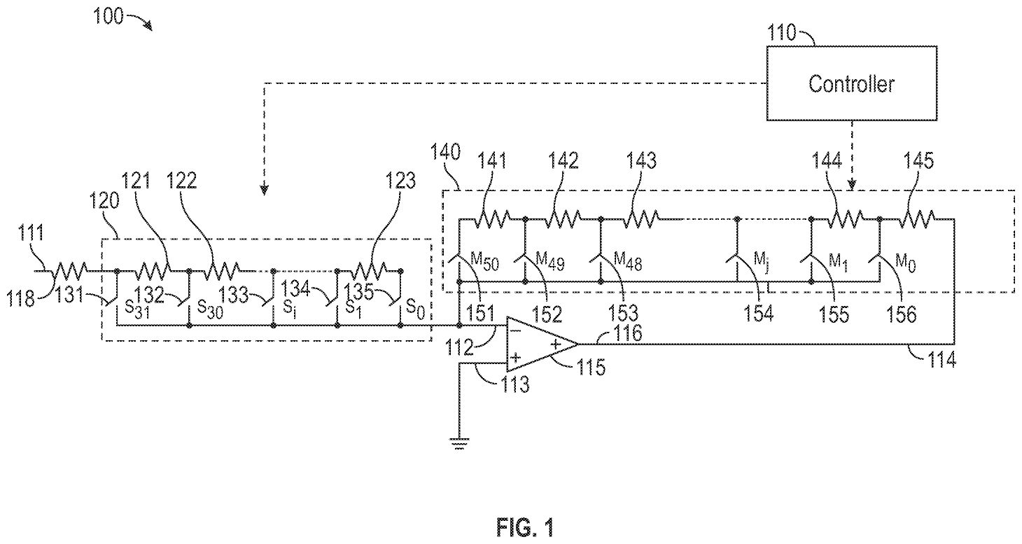

FIG. 1 shows an example of a portion of a PGA circuit 100. The PGA circuit 100 can be configured to adjust a signal gain between a signal input and a signal output. The signal input can be received on the first signal input node 111, and the signal output can be generated on the first signal output node 114. The PGA circuit 100 can include a gain controller circuit 110, a differential-input amplifier 115, a first configurable input impedance circuit 120, and a first configurable feedback impedance circuit 140.

The gain controller circuit 110 can be configured to control one or more of the first configurable input impedance circuit 120 or the first configurable feedback impedance circuit 140, which can include controlling the first configurable input impedance circuit 120 and the first configurable feedback impedance circuit 140 such that the PGA circuit 100 produces a specified value of the signal gain. The gain controller circuit 110 can control the first configurable input impedance circuit 120 such that it is configured to provide a first specified input impedance value. The gain controller circuit 110 can control the first configurable feedback impedance circuit 140 such that it is configured to provide a first specified feedback impedance value. The gain controller circuit 110 can be any circuit capable of controlling the first configurable input impedance circuit 120 or the first configurable feedback impedance circuit 140. The gain controller circuit 110 can include or can be communicatively coupled with one or more of logic circuitry, a processor circuit capable of executing instructions, a memory circuit comprising instructions, or the like.

The differential-input amplifier 115 can be configured to amplify a difference between the signal received on the first input node 112 and the second input node 113 on the first output node 116. The differential-input amplifier 115 can be an amplifier, such as an operational amplifier. The differential-input amplifier 115 can be configured to have one or more properties, such as a high input impedance, a low output impedance, or both. The differential-input amplifier 115 can function to reduce a voltage difference between the first input node 112 and the second input node 113 when a feedback connection from the first output node 116 is provided, such as the first configurable feedback impedance circuit 140. In an example where the differential-input amplifier 115 is an operational amplifier (as shown in FIG. 1), one or more of the first input node 112 can be an inverting input, the second input node 113 can be a non-inverting input, or the first output node 116 can be a non-inverting output. The first output node 116 can comprise the first signal output node 114. The second input node 113 can be coupled to a reference voltage (e.g., a ground potential).

The first configurable input impedance circuit 120 can be configured to provide a first specified input impedance value, such as can one or more of determine the input impedance of the PGA circuit 100 (e.g., the effective impedance experienced by a circuit connected to the first signal input node 111 and looking toward the differential-input amplifier 115) or affect a gain of the PGA circuit 100. In an example, there can be a first input impedance element 118 arranged between the first signal input node 111 and the first configurable input impedance circuit 120. In this example, the input impedance can be the sum of the impedance of the first input impedance element 118 and the first configurable input impedance circuit 120. The first input impedance element 118 can have a specified input impedance element value.

The first configurable input impedance circuit 120 can include a first series arrangement of a first plurality of resistors, and a first plurality of switches. A first end of the first series arrangement can be coupled to the first signal input node 111. Respective connection points between the respective ones of the first plurality of resistors can define respective input impedance tap points. The first series arrangement of the first plurality of resistors can include the first resistor 121, the second resistor 122, and the third resistor 123. One or more of the first resistor 121, the second resistor 122, and the third resistor 123 can be arranged in series. There can be one or more additional resistors in the first series arrangement, which can include one or more additional resistors between the second resistor 122 and the third resistor 123. There can be any number of resistors in the first plurality of resistors, such as can include two resistors, three or more resistors, five or more resistors, 10 or more resistors, 20 or more resistors, 31 resistors (e.g., as shown in FIG. 1), or 40 or more resistors. In an example, all of the resistors in the first plurality of resistors are arranged in series. In an example, one or more of the resistors are arranged in parallel. In an example, the first configurable input impedance circuit 120 can include one or more additional circuit components (e.g., capacitors, inductors), such as can be arranged in series and/or parallel.

The individual ones of the first plurality of resistors can have any specified value. In an example, all of the resistors in the first plurality of resistors can have the same resistance value.

The first plurality of switches can be configured to adjust an impedance of the first configurable input impedance circuit 120. A first end of respective ones of the first plurality of switches can be coupled to the first input node 112 and a second end of respective ones of the first plurality of switches can be coupled to corresponding ones of the input impedance tap points. The first plurality of switches can include a first switch 131, a second switch 132, an i-th switch 133, a fourth switch 134, and a fifth switch 135. There can be one or more additional switches in the first plurality of switches, which can include one or more additional switches between the second switch 132 and the fourth switch 134. In an example, the gain controller circuit 110 can be configured to control the first configurable input impedance circuit 120 by closing an individual one of the first plurality of switches, which can include closing the i-th switch 133. For example, the i-th switch 133 can represent the individual one of the first plurality of switches that is closed, such as can include the first switch 131, the second switch 132, etc.

The second end of the first switch 131 can be coupled to the first input impedance tap point formed before the first resistor 121. The second end of the second switch 132 can be coupled to the second input impedance tap point formed between the first resistor 121 and the second resistor 122. The second end fifth switch 135 can be coupled to the last input impedance tap point formed after the third resistor 123.

The first specified input impedance value can include the sum of the resistance values for all of the resistors between the second end of the first switch 131 and the i-th switch 133 (e.g., the resistance value of the first resistor 121, when the second switch 132 is the selected i-th switch 133). In an example, two or more of the first plurality of switches can be closed at the same time, which can provide a smaller resistance step than closing an individual one of the first plurality of switches at one time.

The first configurable feedback impedance circuit 140 can be configured to provide a first specified feedback impedance value, such as can affect a gain of the PGA circuit 100. The first configurable feedback impedance circuit 140 can be configured similarly to the first configurable input impedance circuit 120, or can differ in one or more ways. The first configurable feedback impedance circuit 140 can include a second series arrangement of a second plurality of resistors. A first end of the second series arrangement can be coupled to the first signal output node 114. Respective connection points between the respective ones of the second plurality of resistors can define respective feedback impedance tap points. The second series arrangement can include the first resistor 141, the second resistor 142, the third resistor 143, the fourth resistor 144, and the fifth resistor 145. One or more of the first resistor 141, the second resistor 142, the third resistor 143, the fourth resistor 144, or the fifth resistor 145 can be arranged in series. There can be one or more additional resistors in the second series arrangement, which can include one or more additional resistors between the third resistor 143 and the fourth resistor 144. There can be any number of resistors in the second plurality of resistors, such as can include two resistors, three or more resistors, five or more resistors, 10 or more resistors, 20 or more resistors, 30 or more resistors, 40 or more resistors, 51 resistors (e.g., as shown in FIG. 1), or 60 or more resistors. In an example, all of the resistors in the second plurality of resistors are arranged in series. In an example, one or more of the resistors are arranged in parallel. In an example, the first configurable feedback impedance circuit 140 can include one or more additional circuit components (e.g., capacitors, inductors), such as can be arranged in series and/or parallel.

The individual ones of the second plurality of resistors can have any specified value. In an example, all of the resistors in the second plurality of resistors can have the same resistance value. One or more of the values of the resistors in the second plurality of resistors can differ from or match one or more of the values of the resistors in the first plurality of resistors.

The second plurality of switches can be configured to adjust an impedance of the first configurable feedback impedance circuit 140. A first end of respective ones of the second plurality of switches can be coupled to the first input node 112 and a second end of respective ones of the first plurality of switches can be coupled to corresponding ones of the feedback impedance tap points. The second plurality of switches can include a first switch 151, a second switch 152, a third switch 153, a j-th switch 154, a fifth switch 155, and a sixth switch 156. There can be one or more additional switches in the second plurality of switches, which can include one or more additional switches between the third switch 153 and the fifth switch 155. In an example, the gain controller circuit 110 can be configured to control the first configurable feedback impedance circuit 140 by closing an individual one of the second plurality of switches, which can include closing the j-th switch 154. For example, the j-th switch 154 can represent the individual one of the second plurality of switches that is closed, such as can include the first switch 151, the second switch 152, etc.

The second end of the first switch 151 can be coupled to the first feedback impedance tap point formed before the first resistor 141. The second end of the second switch 152 can be coupled to the second feedback impedance tap point formed between the first resistor 141 and the second resistor 142. The second end of the sixth switch 156 can be coupled to the last feedback impedance tap point formed between the fourth resistor 144 and the fifth resistor 145.

The first specified feedback impedance value can include the sum of the resistance values for all of the resistors between the first signal output node 114 and the j-th switch 154 (e.g., the sum of the resistance values of the fifth resistor 145, and the fourth resistor 144, when the fifth switch 155 is the selected j-th switch 154). In an example, two or more of the second plurality of switches can be closed at the same time, which can provide a smaller resistance step than closing an individual one of the second plurality of switches at one time.

In the example of FIG. 1, the PGA circuit 100 can include an inverting amplifier configuration. The signal gain of the PGA circuit 100 of FIG. 1 can be shown by equation 1.

$$\\ \begin{matrix}Gain = {V}_{114} / {V}_{111} = - {R}_{feedback} / {R}_{input} = - {R}_{140} / ( {R}_{118} + {R}_{120} ) & Equation 1\end{matrix}$$

In equation 1, V₁₁₄ is the signal output on the first signal output node 114, V₁₁₁ is the signal input on the first signal input node 111, R_{feedback} is the feedback resistance value, Rᵢₙₚᵤₜ is the input resistance value, R₁₄₀ is the first specified feedback impedance value of the first configurable feedback impedance circuit 140, R₁₁₈ is the resistance value of the first input impedance element 118, and R₁₂₀ is the first specified input impedance value of the first configurable input impedance circuit 120. By controlling one or more of the first plurality of switches or the second plurality of switches, the gain controller circuit 110 can control the gain of the PGA circuit 100. The signal input can be based on a difference in the voltage between the first signal input node and the reference voltage. The signal output can be based on the difference between the first signal output node and the reference voltage. Equation 1 shows that the signal gain can be based on a ratio between the feedback resistance value and the input resistance value. This can include a ratio between the first specified feedback impedance value and the first specified input impedance value.

The first configurable input impedance circuit 120 can establish a fine gain control, and the first configurable feedback impedance circuit 140 can establish a coarse gain control. For example, selecting the i-th switch 133 can include adjusting a fine gain control, and selecting the j-th switch 154 can include adjusting a coarse gain control. The gain step due to selecting between adjacent switches (e.g., the first switch 131 and the second switch 132) in the first configurable input impedance circuit 120 can define a fine gain step, which corresponds to a minimum step of the fine gain control. The gain step due to selecting between adjacent switches in the first configurable feedback impedance circuit 140 can define a coarse gain step, which can define a minimum step of the coarse gain control. The gain steps associated with changes of switch states of the first configurable input impedance circuit 120 can be constant, or can vary from step-to-step. One or more fine gain steps can be configured to be within a specified range of one or more other fine gain steps. Similarly, one or more coarse gain steps can be configured to match one or more other coarse gain steps or the step size can be varied depending on resistor values. In an example, adjusting the fine gain control includes changing the individual one of the first plurality of switches that is closed, such as in a mutually-exclusive manner. In an example, adjusting the coarse gain control includes changing an individual one of the second plurality of switches that is closed.

The fine gain steps can be configured to be relatively smaller than the coarse gain steps. In an example, the fine gain steps can be configured to be at least five times smaller than the coarse gain steps. In an example, a total gain change associated with the range between a first and a final fine gain step can approximately match a coarse gain step (e.g., a gain difference between closing the first switch 131 and the fifth switch 135 is approximately equal to a gain difference between closing the first switch 151 and the second switch 152).

In an example, the circuit can be initialized with the fifth switch 135 and the sixth switch 156 closed, and the remaining switches in the first configurable input impedance circuit 120 and the first configurable feedback impedance circuit 140 respectively can be open. In this configuration, the first specified input impedance value can be at a maximum value (e.g., due to all of the first plurality of resistors being arranged in series between the first signal input node 111 and the first input node 112), and the first specified feedback impedance value can be at a minimum value (e.g., due to only a single one of the second plurality of resistors being arranged between the first output node 116 and the first input node 112). This configuration can provide the lowest gain value of the PGA circuit 100. In an example, this lowest gain value can include a unity gain value (e.g., a gain of 0 dB), such as can be due to the first specified input impedance value (e.g., the sum of the first input impedance element 118 and the resistance of the first configurable input impedance circuit 120) matching the first specified feedback impedance value. From this configuration, the gain of the circuit can be increased, such as by closing different switches in the first configurable input impedance circuit 120 or the first configurable feedback impedance circuit 140.

In an example, the signal gain can be increased using the fine gain control, such as can include opening the fifth switch 135 and closing the fourth switch 134. In an example, increasing the fine gain control can include closing a switch in the first plurality of switches that is farther to the left, such as can decrease the value of the first specified input impedance value. In an example, the fine gain control can be stepped through in sequence, such as by closing an individual one of the first plurality of switches in a sequence from right to left (e.g., first the fifth switch 135, then the fourth switch 134, etc.).

In an example, the signal gain can be increased using the coarse gain control, such as can include adjusting the coarse gain control following stepping through one or more of the fine gain steps, such as can include opening the sixth switch 156 and closing the fifth switch 155. In an example, increasing the coarse gain control can include closing a switch in the second plurality of switches that is farther to the left, such as can increase a value of the first specified feedback impedance value. In an example, one or more steps of the fine gain control can be stepped through between adjusting respective steps of the coarse gain control.

In an example, the resistance value of the first input impedance element 118 can be approximately 18.3 kiloohms, and each of the resistors in the first plurality of resistors can have a resistance of approximately 57.6 ohms. This can provide for an input resistance (e.g., resistance of the first input impedance element 118 plus the resistance of the first configurable input impedance circuit 120) range of approximately 18.3 kiloohms to 20.08 kiloohms in 57.6 ohm steps, in a system with 31 resistors in the first plurality of resistors. This can provide for a fine gain step of approximately 0.025 dB or less, such as between all the fine gain steps.

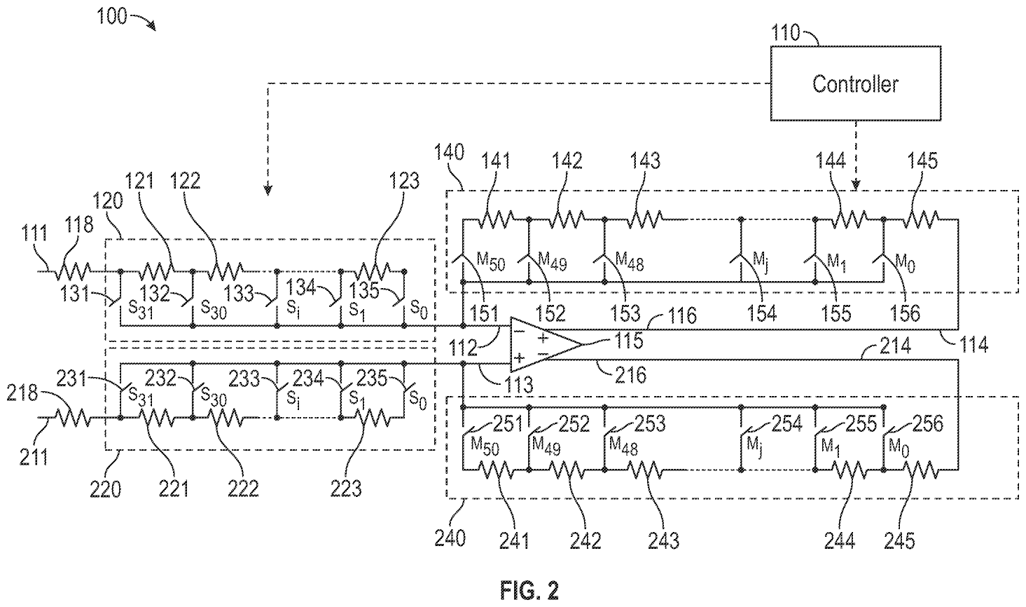

FIG. 2 shows an example of a portion of a PGA circuit 100. The PGA circuit 100 of FIG. 2 can be configured similarly to the PGA circuit 100 of FIG. 1, or can differ in one or more ways. FIG. 2 shows that the differential-input amplifier 115 can include a fully differential-input amplifier, such as can include a second output node 216. The PGA circuit 100 can include a second configurable input impedance circuit 220 and a second configurable feedback impedance circuit 240.

The gain controller circuit 110 can be configured to control one or more of the second configurable input impedance circuit 220 or the second configurable feedback impedance circuit 240. The second output node 216 can include an inverting output. The differential-input amplifier 115 can be configured to amplify a difference in voltage between the first input node 112 and the second input node 113 to a difference in voltage between the first output node 116 and the second output node 216. In an example, the second input node 113 may not be connected to a reference potential.

The second configurable input impedance circuit 220 can be configured similarly to the first configurable input impedance circuit 120, or can differ in one or more ways. The second configurable input impedance circuit 220 can be arranged between a second signal input node 211 and the second input node 113. The second configurable input impedance circuit 220 can be configured to provide a second specified input impedance value. The 220 can include a third series arrangement of third plurality of resistors and a third plurality of switches.

The third plurality of resistors can include the first resistor 221, the second resistor 222, and the third resistor 223. Similar to the first configurable input impedance circuit 120, there can be one or more additional resistors between the second resistor 222 and the third resistor 223. The resistance values of the third plurality of resistors can be configured to match, or one or more resistors can differ from one or more other resistors. In an example, corresponding resistors in the first configurable input impedance circuit 120 have a resistance matching corresponding resistors in the second configurable input impedance circuit 220. In an example, all of the resistors in the first plurality of resistors and the third plurality of resistors can have the same resistance value.

The third plurality of switches can include a first switch 231, a second switch 232, an i-th switch 233, a fourth switch 234, and a fifth switch 235. Similar to the first configurable input impedance circuit 120, the i-th switch 233 can represent the individual switch selected by the gain controller circuit 110 to be closed in a specified configuration. In an example, the first configurable input impedance circuit 120 and the second configurable input impedance circuit 220 can be configured similarly. In an example, the first configurable input impedance circuit 120 and the second configurable input impedance circuit 220 can be operated similarly, such as can result in the first specified input impedance value substantially matching the second specified input impedance value. There can be a second input impedance element 218 arranged in series with the second configurable input impedance circuit 220 between the second signal input node 211 and the first input node 112.

The second configurable feedback impedance circuit 240 can be configured similarly to the first configurable feedback impedance circuit 140, or can differ in one or more ways. The second configurable feedback impedance circuit 240 can be arranged between a second signal output node 214 and the second input node 113. The second configurable feedback impedance circuit 240 can be configured to provide a second specified feedback impedance value. The second configurable feedback impedance circuit 240 can include a fourth series arrangement of a fourth plurality of resistors and a fourth plurality of switches.

The fourth plurality of resistors can include the first resistor 241, the second resistor 242, the third resistor 243, the fourth resistor 244, and the fifth resistor 245. Similar to the first configurable feedback impedance circuit 140, there can be one or more additional resistors between the third resistor 243 and the fourth resistor 244. The resistance values of the fourth plurality of resistors can be configured to match, or one or more of the resistors can differ from one or more other resistors. In an example, corresponding resistors in the first configurable feedback impedance circuit 140 have a resistance matching corresponding resistors in the second configurable feedback impedance circuit 240. In an example, all of the resistors in the second plurality of resistors and the fourth plurality of resistors can have the same resistance value.

The fourth plurality of switches can include the first switch 251, the second switch 252, the third switch 253, the j-th switch 254, the fifth switch 255, and the sixth switch 256. Similar to the first configurable feedback impedance circuit 140, the j-th switch 254 can represent the individual switch selected by the gain controller circuit 110 to be closed in a specific configuration. In an example, the first configurable feedback impedance circuit 140 and the second configurable feedback impedance circuit 240 can be configured similarly. In an example, the first configurable feedback impedance circuit 140 and the second configurable feedback impedance circuit 240 can be operated similarly, such as can result in the first specified feedback impedance value substantially matching the second specified feedback impedance value.

In the fully differential implementation of FIG. 2, the input signal can be based on the difference between the second signal input node 211 and the first signal input node 111, and the output signal can be based on the difference between the second signal output node 214 and the first signal output node 114. The gain of the PGA circuit 100 of FIG. 2 can be shown by equation 1 (e.g., the gain of the PGA circuit 100 of FIG. 2 can match the gain of the PGA circuit 100 of FIG. 1).

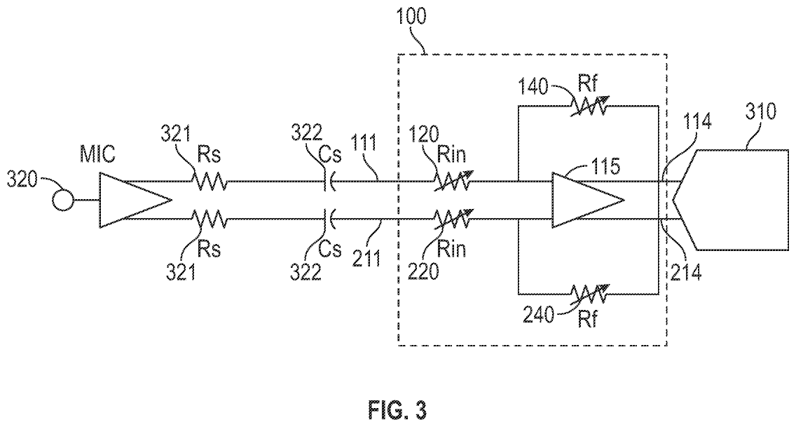

FIG. 3 shows an example of a portion of the PGA circuit 100 of FIG. 2 and an example of an application circuit in which the PGA circuit 100 can be used. FIG. 3 shows that the PGA circuit 100 can receive a signal input from a microphone 320, and can pass the signal output to an audio processing circuitry 310. In an example, the first configurable input impedance circuit 120 and the second configurable input impedance circuit 220 can include the first input impedance element 118 and the second input impedance element 218, respectively.

The microphone 320 can be configured to generate an electrical signal corresponding to a received audio signal. The audio signal can include a pressure disturbance in a medium (e.g., air, water), and can include signals at one or more frequencies (e.g., a periodic audio signal). The microphone 320 can be a transducer that converts sound waves into an electrical signal. The electrical signal from the microphone 320 can be passed to the PGA circuit 100. Passing the signal from the microphone 320 to the PGA circuit 100 can include passing the signal through a coupling resistor 321 or and/or a coupling capacitor 322. In an example, one or more of the coupling resistor 321 or the coupling capacitor 322 can be internal to the microphone 320 or the PGA circuit 100. The input impedance of the PGA circuit 100 experienced by the microphone 320 can include the sum of the impedances of the coupling resistor 321, the coupling capacitor 322, and the first configurable input impedance circuit 120. The coupling capacitor 322 can have the effect of a high-pass filter. The corner frequency of the high-pass filter can be determined as a function of the impedance values of one or more of the coupling resistor 321, the coupling capacitor 322, and the first configurable input impedance circuit 120. Adjusting the first configurable input impedance circuit 120, such as to adjust a gain of the PGA circuit 100, can have the effect of changing the corner frequency of the filter. This can make it desirable to minimize a change in the resistance value of the first configurable input impedance circuit 120, such as to help maintain a consistent frequency response.

The audio processing circuitry 310 can include one or more of an analog-to-digital converter or other audio processing circuitry. The audio processing circuitry 310 can be used in a process, such as one or more of audio digitization for storage or communications applications, noise cancelation, or the like. The PGA circuit 100 can scale the input signal to the audio processing circuitry 310 to an appropriate range, such as an appropriate range for digitization or other downstream processing. This can help a dynamic range of the signal provided to the ADC should approximately match the ADC dynamic range, such as can help to maximize or otherwise tailor SNR. In an example, the 310 can amplify a signal received from the PGA circuit 100, such as can include amplifying an audio signal to be sent to one or more speakers. In this example, the audio processing circuitry 310 can have a specified gain value, such as can include an adjustable gain value.

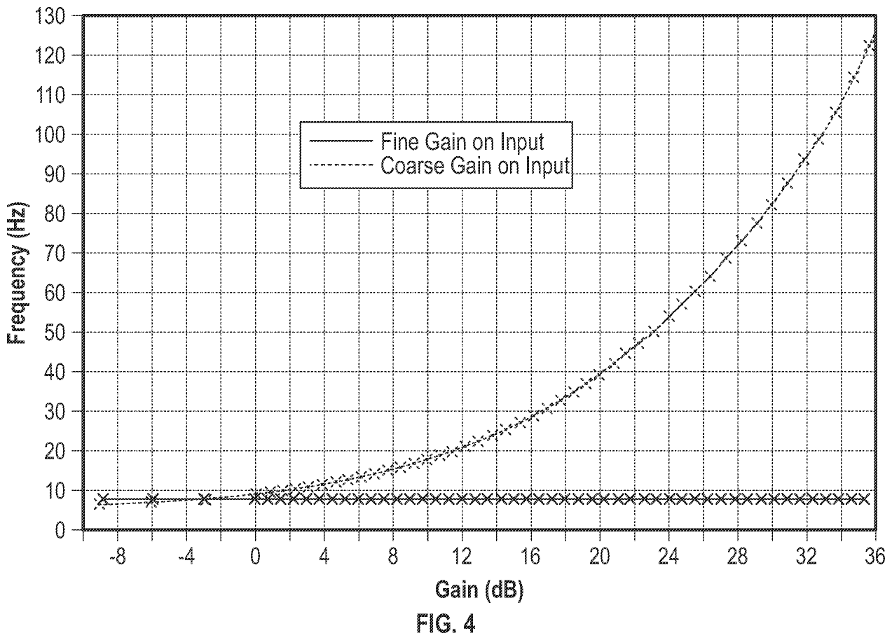

FIG. 4 shows a plot of simulated operating characteristics of a PGA circuit 100 as shown in FIG. 3. FIG. 4 shows the corner frequency of the high-pass filter formed by the input impedance of the PGA circuit 100 across a range of signal gain values. When the first configurable input impedance circuit 120 and the second configurable input impedance circuit 220 (e.g., the input) include the fine gain control, the input impedance remains substantially the same across the gain range, such as at approximately 8 Hz, such as can be due to the input impedance remaining relatively constant (e.g., changing less than 10 percent). When the first configurable input impedance circuit 120 and the second configurable input impedance circuit 220 include the coarse gain control, such as in a case where the fine gain control is not present or is present in one or more of the first configurable input impedance circuit 120, the second configurable input impedance circuit 220, the first configurable feedback impedance circuit 140 or the second configurable feedback impedance circuit 240, the corner frequency can change across the gain range, such as from a value of approximately 8 Hz to 125 Hz. When the coarse gain control is on the input, the corner frequency shifts substantially in response to changing can.

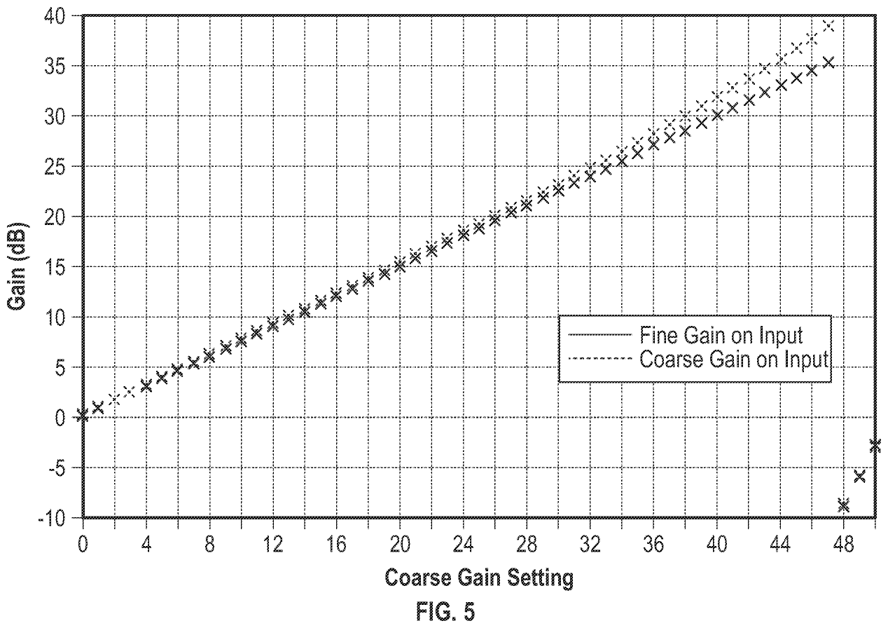

FIG. 5 shows a plot of simulated operating characteristics of a PGA circuit 100 as shown in FIG. 3. FIG. 5 shows the gain of the PGA circuit 100 across a range of coarse gain control settings (e.g., selecting between the first switch 151 and the second switch 152, etc.). FIG. 5 shows that when the fine gain control is on the input, the gain steps are relatively linear. When the coarse gain control is on the input, such as in a case where the fine gain control is not present or is present on the feedback, the gain steps are not as linear, such as can be due to a changing corner frequency of the high pass filter, as discussed above with respect to FIG. 4.

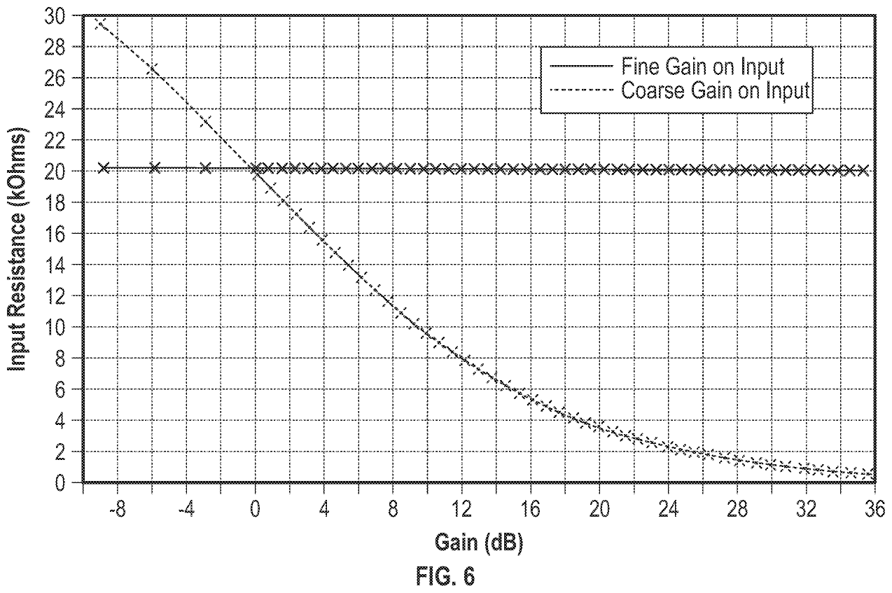

FIG. 6 shows a plot of simulated operating characteristics of a PGA circuit 100 as shown in FIG. 3. FIG. 6 shows the input resistance of the PGA circuit 100 across a range of signal gains for the coarse gain control. FIG. 6 shows that when the fine gain control is on the input, such as in a case where the fine gain control is not present or is present on the feedback, the input resistance of the PGA circuit 100 remains relatively constant, such as at approximately 20 kiloohms. When the coarse gain control is on the input, the input resistance varies, such as from approximately 29.5 kiloohms to 0.3 kiloohms.

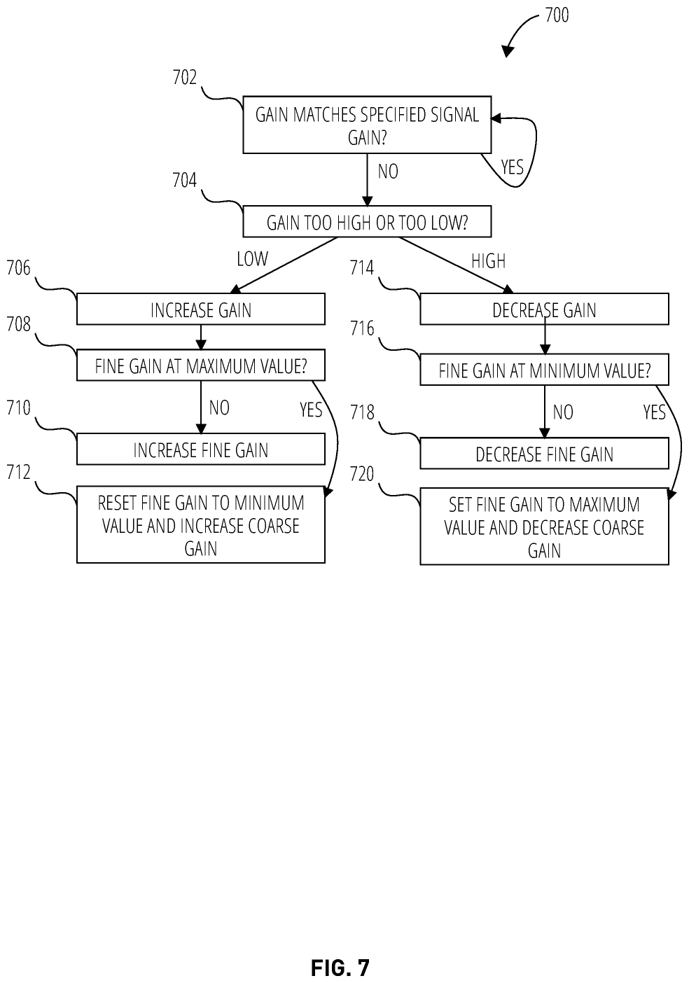

FIG. 7 shows an example of portions of a method 700 for operating a PGA circuit, such as the PGA circuit 100. At step 702, a signal gain can be compared to a specified signal gain. For example, an effective signal gain of the PGA circuit 100 can be compared to a specified signal gain. The specified signal gain can be determined by the gain controller circuit 110, a user, or both. The signal gain can be determined by comparing the signal input to the signal output. The signal gain can be compared to the specified signal gain in digital logic, analog logic, or both. If the signal gain matches the specified signal gain (e.g., matches within a specified tolerance, such as can be approximately equal to the fine gain step), the method 700 can include returning to step 702, such as to recurrently compare the signal gain to the specified signal gain. If the signal gain does not match the specified signal gain, the method 700 can include going to step 704.

At step 704, it can be determined if the gain is too high or too low. This can include comparing the signal gain to the specified signal gain. If the gain is too high, the method 700 can include going to step 714. If the gain is too low, the method 700 can include going to step 706.

At step 706, the signal gain can be increased. Increasing the signal gain can include, at step 708, checking whether the fine gain control is at an upper limit (e.g., whether the fine gain control configured to produce the maximum signal gain). If the fine gain control is not at the upper limit, the fine gain control can be increased at step 710, such as can include adjusting the fine gain control in the direction indicated by the comparison at step 704. If the fine gain control is at an upper limit, the fine gain control can be reset to a lower limit, and the coarse gain control can be increased at step 712. In an example, the system can be configured such that the gain increase by resetting the fine gain control and increasing the coarse gain control is approximately equal to one step of the fine gain control. In an example, the fine gain control may not be reset to the lowest setting, but may be set to an intermediate setting, such as to produce the desired gain step size (e.g., resetting the fine gain control while increasing the coarse gain control could cause a decrease in gain for some coarse gain settings, which may not be desirable). Following step 710 or step 712, the method 700 can include returning to step 702.

At step 714, the signal gain can be decreased. Decreasing the signal gain can include, at step 716, checking whether the fine gain control is at a lower limit. If the fine gain control is not at the lower limit, the fine gain control can be decreased at step 718. If the fine gain control is at a lower limit, the fine gain control can be set to the upper limit, and the coarse gain control can be decreased at step 720. Following step 718 or step 720, the method 700 can include returning to step 702.

The shown order of steps is not intended to be a limitation on the order the steps are performed in. In an example, two or more steps may be performed simultaneously or at least partially concurrently.

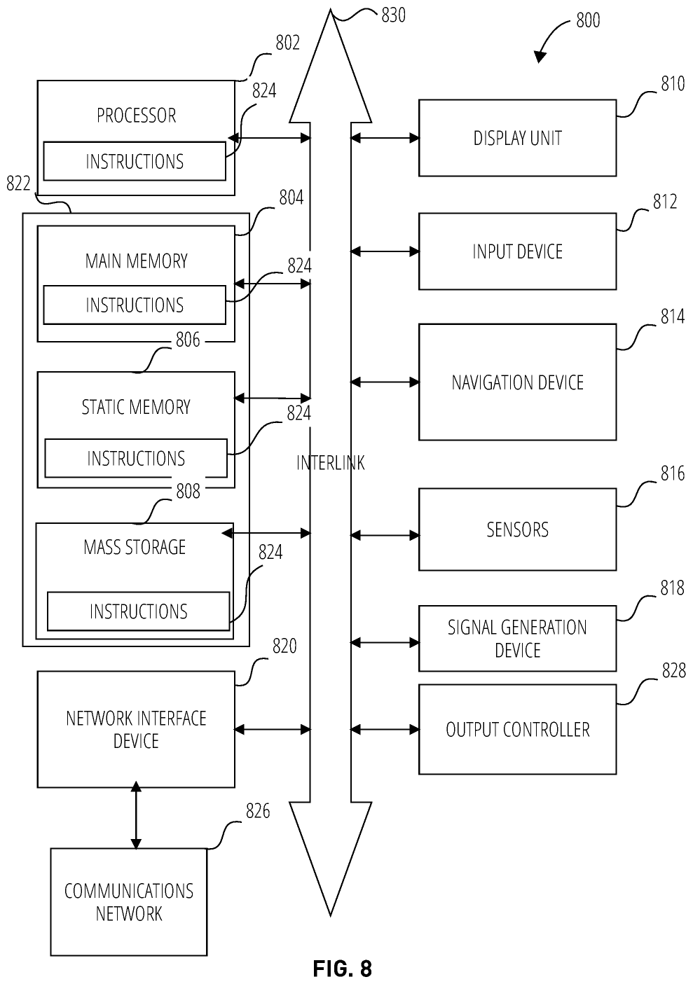

FIG. 8 illustrates a block diagram of an example machine 800 upon which any one or more of the techniques (e.g., methodologies) discussed herein may be implemented. Examples, as described herein, may include, or may operate by, logic or a number of components, or mechanisms in the machine 800. Circuitry (e.g., processing circuitry) is a collection of circuits implemented in tangible entities of the machine 800 that include hardware (e.g., simple circuits, gates, logic, etc.). Circuitry membership may be flexible over time. Circuitries include members that may, alone or in combination, perform specified operations when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a machine readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuitry in hardware via the variable connections to carry out portions of the specific operation when in operation. Accordingly, in an example, the machine readable medium elements are part of the circuitry or are communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time. Additional examples of these components with respect to the machine 800 follow.

In alternative examples, the machine 800 may operate as a standalone device or may be connected (e.g., networked) to other machines. In a networked deployment, the machine 800 may operate in the capacity of a server machine, a client machine, or both in server-client network environments. In an example, the machine 800 may act as a peer machine in peer-to-peer (P2P) (or other distributed) network environment. The machine 800 may be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (Saas), other computer cluster configurations.

The machine 800 may include a hardware processor 802 (e.g., a central processing unit (CPU), a graphics processing unit (GPU), a hardware processor core, or any combination thereof), a main memory 804, a static memory (e.g., memory or storage for firmware, microcode, a basic-input-output (BIOS), and mass storage 808 (e.g., hard drives, tape drives, flash storage, or other block devices) some or all of which may communicate with each other via an interlink 830 (e.g., bus). The machine 800 may further include a display unit 810, an alphanumeric input device 812 (e.g., a keyboard), and a user interface (UI) navigation device 814 (e.g., a mouse). In an example, the display unit 810, input device 812 and UI navigation device 814 may be a touch screen display. The machine 800 may additionally include a signal generation device 818 (e.g., a speaker), a network interface device 820, and one or more sensors 816, such as a global positioning system (GPS) sensor, compass, accelerometer, or other sensor. The machine 800 may include an output controller 828, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Registers of the processor 802, the main memory 804, the static memory 806, or the mass storage 808 may be, or include, a machine readable medium 822 on which is stored one or more sets of data structures or instructions 824 (e.g., software) embodying or utilized by any one or more of the techniques or functions described herein. The instructions 824 may also reside, completely or at least partially, within any of registers of the processor 802, the main memory 804, the static memory 806, or the mass storage 808 during execution thereof by the machine 800. In an example, one or any combination of the hardware processor 802, the main memory 804, the static memory 806, or the mass storage 808 may constitute the machine readable media 822. While the machine readable medium 822 is illustrated as a single medium, the term “machine readable medium” may include a single medium or multiple media (e.g., a centralized or distributed database, and/or associated caches and servers) configured to store the one or more instructions 824.

The term “machine readable medium” may include any medium that is capable of storing, encoding, or carrying instructions for execution by the machine 800 and that cause the machine 800 to perform any one or more of the techniques of the present disclosure, or that is capable of storing, encoding or carrying data structures used by or associated with such instructions. Non-limiting machine readable medium examples may include solid-state memories, optical media, magnetic media, and signals (e.g., radio frequency signals, other photon based signals, sound signals, etc.). In an example, a non-transitory machine readable medium comprises a machine readable medium with a plurality of particles having invariant (e.g., rest) mass, and thus are compositions of matter. Accordingly, non-transitory machine-readable media are machine readable media that do not include transitory propagating signals. Specific examples of non-transitory machine readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

In an example, information stored or otherwise provided on the machine readable medium 822 may be representative of the instructions 824, such as instructions 824 themselves or a format from which the instructions 824 may be derived. This format from which the instructions 824 may be derived may include source code, encoded instructions (e.g., in compressed or encrypted form), packaged instructions (e.g., split into multiple packages), or the like. The information representative of the instructions 824 in the machine readable medium 822 may be processed by processing circuitry into the instructions to implement any of the operations discussed herein. For example, deriving the instructions 824 from the information (e.g., processing by the processing circuitry) may include: compiling (e.g., from source code, object code, etc.), interpreting, loading, organizing (e.g., dynamically or statically linking), encoding, decoding, encrypting, unencrypting, packaging, unpackaging, or otherwise manipulating the information into the instructions 824.

In an example, the derivation of the instructions 824 may include assembly, compilation, or interpretation of the information (e.g., by the processing circuitry) to create the instructions 824 from some intermediate or preprocessed format provided by the machine readable medium 822. The information, when provided in multiple parts, may be combined, unpacked, and modified to create the instructions 824. For example, the information may be in multiple compressed source code packages (or object code, or binary executable code, etc.) on one or several remote servers. The source code packages may be encrypted when in transit over a network and decrypted, uncompressed, assembled (e.g., linked) if necessary, and compiled or interpreted (e.g., into a library, stand-alone executable etc.) at a local machine, and executed by the local machine.

The instructions 824 may be further transmitted or received over a communications network 826 using a transmission medium via the network interface device 820 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), LoRa/LoRaWAN, or satellite communication networks, mobile telephone networks (e.g., cellular networks such as those complying with 3G, 4G LTE/LTE-A, or 5G standards), Plain Old Telephone (POTS) networks, and wireless data networks (e.g., Institute of Electrical and Electronics Engineers (IEEE) 802.11 family of standards known as Wi-Fi®, IEEE 802.15.4 family of standards, peer-to-peer (P2P) networks, among others. In an example, the network interface device 820 may include one or more physical jacks (e.g., Ethernet, coaxial, or phone jacks) or one or more antennas to connect to the communications network 826. In an example, the network interface device 820 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 800, and includes digital or analog communications signals or other intangible medium to facilitate communication of such software. A transmission medium is a machine-readable medium.

The following, non-limiting examples, detail certain aspects of the present subject matter to solve the challenges and provide the benefits discussed herein, among others.

### EXAMPLES

Example 1 is a programmable gain amplifier (PGA) circuit for adjusting a signal gain between a signal input and a signal output, the PGA circuit comprising: a differential-input amplifier comprising a first input node, a second input node, and a first output node, wherein the differential-input amplifier is configured to amplify a difference in signal level between the first input node and the second input node for being provided on the first output node; a first configurable input impedance circuit, arranged between a first signal input node and the first input node, wherein the first configurable input impedance circuit is configured to provide a first specified input impedance value; wherein the first configurable input impedance circuit includes: a first series arrangement of a first plurality of resistors, wherein a first end of the first series arrangement is coupled to the first signal input node, wherein respective connection points between respective ones of the first plurality of resistors define respective input impedance tap points; and a first plurality of switches, wherein a first end of respective ones of the first plurality of switches is coupled to the first input node and a second end of the respective ones of the first plurality of switches is coupled to corresponding ones of the input impedance tap points; and a first configurable feedback impedance circuit, arranged between a first signal output node and the first input node, wherein the first configurable feedback impedance circuit is configured to provide a first specified feedback impedance value, wherein the first configurable feedback impedance circuit includes: a second series arrangement of a second plurality of resistors, wherein a first end of the second series arrangement is coupled to the first signal output node, wherein respective connection points between respective ones of the second plurality of resistors define respective feedback impedance tap points; and a second plurality of switches, wherein a first end of respective ones of the second plurality of switches is coupled to the first input node and a second end of the respective ones of the second plurality of switches is coupled to corresponding ones of the feedback impedance tap points.
In Example 2, the subject matter of Example 1 optionally includes a gain controller circuit, coupled to the first configurable input impedance circuit and the first configurable feedback impedance circuit, wherein the gain controller circuit is configured to control the first specified input impedance value and the first specified feedback impedance value such that the PGA circuit provides a specified value of the signal gain.
In Example 3, the subject matter of Example 2 optionally includes wherein the gain controller circuit is configured to: control the first configurable input impedance circuit by closing an individual one of the first plurality of switches; and control the first configurable feedback impedance circuit by closing an individual one of the second plurality of switches.
In Example 4, the subject matter of any one or more of Examples 1-3 optionally include wherein: each of the first plurality of resistors include a same first resistance value; and each of the second plurality of resistors include a same second resistance value.
In Example 5, the subject matter of any one or more of Examples 1-4 optionally include wherein: the second input node is coupled to a reference voltage; the signal input is based on a difference in voltage between the first signal input node and the reference voltage; and the signal output is based on a difference in voltage between the first signal output node and the reference voltage.
In Example 6, the subject matter of any one or more of Examples 1-5 optionally include wherein: the differential-input amplifier includes a fully differential-input amplifier, including a second output node; the PGA circuit includes: a second configurable input impedance circuit, arranged between a second signal input node and the second input node, wherein the second configurable input impedance circuit is configured to provide a second specified input impedance value; and a second configurable feedback impedance circuit, arranged between a second signal output node and the second input node, wherein the second configurable feedback impedance circuit is configured to provide a second specified feedback impedance value; and the signal input it based on a difference in voltage between the first signal input node and the second signal input node; and the signal output is based on a difference in voltage between the first signal output node and the second signal output node.
In Example 7, the subject matter of Example 6 optionally includes wherein the PGA circuit is configured such that: the second specified input impedance value matches the first specified input impedance value; and the second specified feedback impedance value matches the first specified feedback impedance value.
In Example 8, the subject matter of any one or more of Examples 1-7 optionally include wherein: a ratio between the first specified feedback impedance value and the first specified input impedance value determines the signal gain.
In Example 9, the subject matter of Example 8 optionally includes wherein: adjusting the first specified input impedance value comprises adjusting a fine gain control; and adjusting the first specified feedback impedance value comprises adjusting a coarse gain control; and wherein a minimum adjustment of the fine gain control comprises and adjustment at least five times smaller than a minimum adjustment of the coarse gain control.
In Example 10, the subject matter of any one or more of Examples 1-9 optionally include an input impedance element, arranged between the first signal input node and the first configurable input impedance circuit, wherein the input impedance element includes a specified input impedance element value.
In Example 11, the subject matter of Example 10 optionally includes wherein: the specified input impedance element value is at least five times greater than a difference between a maximum and a minimum value of the first specified input impedance value.
In Example 12, the subject matter of any one or more of Examples 1-11 optionally include wherein: the PGA circuit is arranged to amplify a signal from a microphone; and the microphone includes a capacitance in series with the first signal input node.
Example 13 is a method of operating a programmable gain amplifier (PGA) circuit for adjusting a signal gain between a signal input and a signal output, the method comprising: comparing the signal gain to a specified signal gain; adjusting a fine gain control in a direction indicated by the comparison; and in response to the fine gain control reaching one of an upper limit or a lower limit, adjusting a coarse gain control in the direction indicated by the comparison and setting the fine gain control to one of the upper limit or the lower limit opposite to the limit reached, wherein the PGA circuit includes: a differential-input amplifier including a first input node, a second input node, and a first output node, wherein the differential-input amplifier is configured to amplify a difference in signal level between the first input node and the second input node for being provided at the first output node; a first configurable input impedance circuit, arranged between a first signal input node and the first input node, wherein the first configurable input impedance circuit is configured to provide a first specified input impedance value; and a first configurable feedback impedance circuit, arranged between a first signal output node and the first input node, wherein the first configurable feedback impedance circuit is configured to provide a first specified feedback impedance value.
In Example 14, the subject matter of Example 13 optionally includes wherein: adjusting the first specified input impedance value comprises adjusting the fine gain control; and adjusting the first specified feedback impedance value comprises adjusting the coarse gain control.
In Example 15, the subject matter of any one or more of Examples 13-14 optionally include wherein: a first gain change due to: (1) to adjusting the coarse gain control in the direction indicated by the comparison, and (2) setting the fine gain control to one of the upper limit or the lower limit opposite to the limit reached, is configured to match a gain change due to adjusting the fine gain control in a direction indicated by the comparison.
In Example 16, the subject matter of any one or more of Examples 13-15 optionally include wherein: the first configurable input impedance circuit includes: a first series arrangement of a first plurality of resistors, wherein a first end of the first series arrangement is coupled to the first signal input node, wherein respective connection points between respective ones of the first plurality of resistors define respective input impedance tap points; and a first plurality of switches, wherein a first end of respective ones of the first plurality of switches is coupled to the first input node and a second end of the respective ones of the first plurality of switches is coupled to corresponding ones of the input impedance tap points; and the first configurable feedback impedance circuit includes: a second series arrangement of a second plurality of resistors, wherein a first end of the second series arrangement is coupled to the first signal output node, wherein respective connection points between respective ones of the second plurality of resistors define respective feedback impedance tap points; and a second plurality of switches, wherein a first end of respective ones of the second plurality of switches is coupled to the first input node and a second end of the respective ones of the second plurality of switches is coupled to corresponding ones of the feedback impedance tap points.
In Example 17, the subject matter of Example 16 optionally includes controlling the first configurable input impedance circuit by closing an individual one of the first plurality of switches; and controlling the first configurable feedback impedance circuit by closing an individual one of the second plurality of switches, wherein: adjusting the fine gain control includes changing the individual one of the first plurality of switches that is closed; and adjusting the coarse gain control includes changing the individual one of the second plurality of switches that is closed.
Example 18 is at least one non-transitory machine-readable medium for controlling a programmable gain amplifier (PGA) circuit for adjusting a signal gain between a signal input and a signal output, including instructions, which when executed, cause processing circuitry to perform operations to: compare the signal gain to a specified signal gain; adjust a fine gain control in a direction indicated by the comparison; and in response to the fine gain control reaching one of an upper limit or a lower limit, adjust a coarse gain control in the direction indicated by the comparison and setting the fine gain control to one of the upper limit or the lower limit opposite to the limit reached, wherein the PGA circuit includes: a differential-input amplifier include a first input node, a second input node, and a first output node, wherein the differential-input amplifier is configured to amplify a difference in signal level between the first input node and the second input node for being provided at the first output node; a first configurable input impedance circuit, arranged between a first signal input node and the first input node, wherein the first configurable input impedance circuit is configured to provide a first specified input impedance value; and a first configurable feedback impedance circuit, arranged between a first signal output node and the first input node, wherein the first configurable feedback impedance circuit is configured to provide a first specified feedback impedance value.
In Example 19, the subject matter of Example 18 optionally includes wherein: to adjust the first specified input impedance value comprises adjusting the fine gain control; and to adjust the first specified feedback impedance value comprises adjusting the coarse gain control.
In Example 20, the subject matter of any one or more of Examples 18-19 optionally include wherein: the first configurable input impedance circuit includes: a first series arrangement of a first plurality of resistors, wherein a first end of the first series arrangement is coupled to the first signal input node, wherein respective connection points between respective ones of the first plurality of resistors define respective input impedance tap points; and a first plurality of switches, wherein a first end of respective ones of the first plurality of switches is coupled to the first input node and a second end of the respective ones of the first plurality of switches is coupled to corresponding ones of the input impedance tap points; and the first configurable feedback impedance circuit includes: a second series arrangement of a second plurality of resistors, wherein a first end of the second series arrangement is coupled to the first signal output node, wherein respective connection points between respective ones of the second plurality of resistors define respective feedback impedance tap points; and a second plurality of switches, wherein a first end of respective ones of the second plurality of switches is coupled to the first input node and a second end of the respective ones of the second plurality of switches is coupled to corresponding ones of the feedback impedance tap points.
Example 21 is at least one machine-readable medium including instructions that, when executed by processing circuitry, cause the processing circuitry to perform operations to implement of any of Examples 1-20.
Example 22 is an apparatus comprising means to implement of any of Examples 1-20.
Example 23 is a system to implement of any of Examples 1-20.
Example 24 is a method to implement of any of Examples 1-20.

Each of the non-limiting aspects above can stand on its own or can be combined in various permutations or combinations with one or more of the other aspects or other subject matter described in this document.

The above detailed description includes references to the accompanying drawings, which form a part of the detailed description. The drawings show, by way of illustration, specific examples that may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the terms “or” and “and/or” are used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The term “about,” as used herein, means approximately, in the region of, roughly, or around. When the term “about” is used in conjunction with a numerical range, it modifies that range by extending the boundaries above and below the numerical values set forth. In general, the term “about” is used herein to modify a numerical value above and below the stated value by a variance of 10%. In one aspect, the term “about” means plus or minus 10% of the numerical value of the number with which it is being used. Therefore, about 50% means in the range of 45%-55%. Numerical ranges recited herein by endpoints include all numbers and fractions subsumed within that range (e.g., 1 to 5 includes 1, 1.5, 2, 2.75, 3, 3.90, 4, 4.24, and 5). Similarly, numerical ranges recited herein by endpoints include subranges subsumed within that range (e.g., 1 to 5 includes 1-1.5, 1.5-2, 2-2.75, 2.75-3, 3-3.90, 3.90-4, 4-4.24, 4.24-5, 2-5, 3-5, 1-4, and 2-4).

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Such instructions can be read and executed by one or more processors to enable performance of operations comprising a method, for example. The instructions are in any suitable form, such as but not limited to source code, compiled code, interpreted code, executable code, static code, dynamic code, and the like.

Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other examples may be used, such as by one of ordinary skill in the art upon reviewing the above description. The Abstract is to allow the reader to quickly ascertain the nature of the technical disclosure and is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the examples should be determined with reference to the appended claims, along with the full scope of equivalents to which such claims are entitled.

What is claimed is:

1. A programmable gain amplifier (PGA) circuit for adjusting a signal gain between a signal input and a signal output, the PGA circuit comprising:
a differential-input amplifier comprising a first input node, a second input node, and a first output node, wherein the differential-input amplifier is configured to amplify a difference in signal level between the first input node and the second input node for being provided on the first output node;
a first configurable input impedance circuit, arranged between a first signal input node and the first input node, wherein the first configurable input impedance circuit is configured to provide a first specified input impedance value; wherein the first configurable input impedance circuit includes:
a first series arrangement of a first plurality of resistors, wherein a first end of the first series arrangement is coupled to the first signal input node, wherein respective connection points between respective ones of the first plurality of resistors define respective input impedance tap points; and
a first plurality of switches, wherein a first end of respective ones of the first plurality of switches is coupled to the first input node and a second end of the respective ones of the first plurality of switches is coupled to corresponding ones of the input impedance tap points; and
a first configurable feedback impedance circuit, arranged between a first signal output node and the first input node, wherein the first configurable feedback impedance circuit is configured to provide a first specified feedback impedance value, wherein the first configurable feedback impedance circuit includes:
a second series arrangement of a second plurality of resistors, wherein a first end of the second series arrangement is coupled to the first signal output node, wherein respective connection points between respective ones of the second plurality of resistors define respective feedback impedance tap points; and
a second plurality of switches, wherein a first end of respective ones of the second plurality of switches is coupled to the first input node and a second end of the respective ones of the second plurality of switches is coupled to corresponding ones of the feedback impedance tap points.

2. The PGA circuit of claim 1, comprising:
a gain controller circuit, coupled to the first configurable input impedance circuit and the first configurable feedback impedance circuit, wherein the gain controller circuit is configured to control the first specified input impedance value and the first specified feedback impedance value such that the PGA circuit provides a specified value of the signal gain.

3. The PGA circuit of claim 2, wherein the gain controller circuit is configured to:
control the first configurable input impedance circuit by closing an individual one of the first plurality of switches; and
control the first configurable feedback impedance circuit by closing an individual one of the second plurality of switches.

4. The PGA circuit of claim 1, wherein:
each of the first plurality of resistors include a same first resistance value; and
each of the second plurality of resistors include a same second resistance value.

5. The PGA circuit of claim 1, wherein:
the second input node is coupled to a reference voltage;
the signal input is based on a difference in voltage between the first signal input node and the reference voltage; and
the signal output is based on a difference in voltage between the first signal output node and the reference voltage.

6. The PGA circuit of claim 1, wherein:
the differential-input amplifier includes a fully differential-input amplifier, including a second output node;
the PGA circuit includes:
a second configurable input impedance circuit, arranged between a second signal input node and the second input node, wherein the second configurable input impedance circuit is configured to provide a second specified input impedance value; and
a second configurable feedback impedance circuit, arranged between a second signal output node and the second input node, wherein the second configurable feedback impedance circuit is configured to provide a second specified feedback impedance value; and
the signal input it based on a difference in voltage between the first signal input node and the second signal input node; and
the signal output is based on a difference in voltage between the first signal output node and the second signal output node.

7. The PGA circuit of claim 6, wherein the PGA circuit is configured such that:
the second specified input impedance value matches the first specified input impedance value; and
the second specified feedback impedance value matches the first specified feedback impedance value.

8. The PGA circuit of claim 1, wherein:
a ratio between the first specified feedback impedance value and the first specified input impedance value determines the signal gain.

9. The PGA circuit of claim 8, wherein:
adjusting the first specified input impedance value comprises adjusting a fine gain control; and
adjusting the first specified feedback impedance value comprises adjusting a coarse gain control; and
wherein a minimum adjustment of the fine gain control comprises and adjustment at least five times smaller than a minimum adjustment of the coarse gain control.

10. The PGA circuit of claim 1, comprising:
an input impedance element, arranged between the first signal input node and the first configurable input impedance circuit, wherein the input impedance element includes a specified input impedance element value.

11. The PGA circuit of claim 10, wherein:
the specified input impedance element value is at least five times greater than a difference between a maximum and a minimum value of the first specified input impedance value.

12. The PGA circuit of claim 1, wherein:
the PGA circuit is arranged to amplify a signal from a microphone; and
the microphone includes a capacitance in series with the first signal input node.

13. A method of operating a programmable gain amplifier (PGA) circuit for adjusting a signal gain between a signal input and a signal output, the method comprising:
comparing the signal gain to a specified signal gain;
adjusting a fine gain control in a direction indicated by the comparison; and
in response to the fine gain control reaching one of an upper limit or a lower limit, adjusting a coarse gain control in the direction indicated by the comparison and setting the fine gain control to one of the upper limit or the lower limit opposite to the limit reached, wherein the PGA circuit includes:
a differential-input amplifier including a first input node, a second input node, and a first output node, wherein the differential-input amplifier is configured to amplify a difference in signal level between the first input node and the second input node for being provided at the first output node;
a first configurable input impedance circuit, arranged between a first signal input node and the first input node, wherein the first configurable input impedance circuit is configured to provide a first specified input impedance value; and
a first configurable feedback impedance circuit, arranged between a first signal output node and the first input node, wherein the first configurable feedback impedance circuit is configured to provide a first specified feedback impedance value.

14. The method of claim 13, wherein:
adjusting the first specified input impedance value comprises adjusting the fine gain control; and
adjusting the first specified feedback impedance value comprises adjusting the coarse gain control.

15. The method of claim 13, wherein:
a first gain change due to: (1) to adjusting the coarse gain control in the direction indicated by the comparison, and (2) setting the fine gain control to one of the upper limit or the lower limit opposite to the limit reached, is configured to match a gain change due to adjusting the fine gain control in a direction indicated by the comparison.

16. The method of claim 13, wherein:
the first configurable input impedance circuit includes:
a first series arrangement of a first plurality of resistors, wherein a first end of the first series arrangement is coupled to the first signal input node, wherein respective connection points between respective ones of the first plurality of resistors define respective input impedance tap points; and
a first plurality of switches, wherein a first end of respective ones of the first plurality of switches is coupled to the first input node and a second end of the respective ones of the first plurality of switches is coupled to corresponding ones of the input impedance tap points; and
the first configurable feedback impedance circuit includes:
a second series arrangement of a second plurality of resistors, wherein a first end of the second series arrangement is coupled to the first signal output node, wherein respective connection points between respective ones of the second plurality of resistors define respective feedback impedance tap points; and
a second plurality of switches, wherein a first end of respective ones of the second plurality of switches is coupled to the first input node and a second end of the respective ones of the second plurality of switches is coupled to corresponding ones of the feedback impedance tap points.

17. The method of claim 16, comprising:
controlling the first configurable input impedance circuit by closing an individual one of the first plurality of switches; and
controlling the first configurable feedback impedance circuit by closing an individual one of the second plurality of switches, wherein:
adjusting the fine gain control includes changing the individual one of the first plurality of switches that is closed; and
adjusting the coarse gain control includes changing the individual one of the second plurality of switches that is closed.

18. At least one non-transitory machine-readable medium for controlling a programmable gain amplifier (PGA) circuit for adjusting a signal gain between a signal input and a signal output, including instructions, which when executed, cause processing circuitry to perform operations to:
compare the signal gain to a specified signal gain;
adjust a fine gain control in a direction indicated by the comparison; and
in response to the fine gain control reaching one of an upper limit or a lower limit, adjust a coarse gain control in the direction indicated by the comparison and setting the fine gain control to one of the upper limit or the lower limit opposite to the limit reached, wherein the PGA circuit includes:
a differential-input amplifier include a first input node, a second input node, and a first output node, wherein the differential-input amplifier is configured to amplify a difference in signal level between the first input node and the second input node for being provided at the first output node;
a first configurable input impedance circuit, arranged between a first signal input node and the first input node, wherein the first configurable input impedance circuit is configured to provide a first specified input impedance value; and
a first configurable feedback impedance circuit, arranged between a first signal output node and the first input node, wherein the first configurable feedback impedance circuit is configured to provide a first specified feedback impedance value.

19. The at least one non-transitory machine-readable medium of claim 18, wherein:
to adjust the first specified input impedance value comprises adjusting the fine gain control; and
to adjust the first specified feedback impedance value comprises adjusting the coarse gain control.

20. The at least one non-transitory machine-readable medium of claim 18, wherein:
the first configurable input impedance circuit includes:
a first series arrangement of a first plurality of resistors, wherein a first end of the first series arrangement is coupled to the first signal input node, wherein respective connection points between respective ones of the first plurality of resistors define respective input impedance tap points; and
a first plurality of switches, wherein a first end of respective ones of the first plurality of switches is coupled to the first input node and a second end of the respective ones of the first plurality of switches is coupled to corresponding ones of the input impedance tap points; and
the first configurable feedback impedance circuit includes:
a second series arrangement of a second plurality of resistors, wherein a first end of the second series arrangement is coupled to the first signal output node, wherein respective connection points between respective ones of the second plurality of resistors define respective feedback impedance tap points; and
a second plurality of switches, wherein a first end of respective ones of the second plurality of switches is coupled to the first input node and a second end of the respective ones of the second plurality of switches is coupled to corresponding ones of the feedback impedance tap points.
